(19) United States
(12) Patent Application Publication
(10) Pub. No.: US 2018/0002803 A1
(43) Pub. Date: Jan. 4, 2018

(54) DEPOSITION MASK, DEPOSITION DEVICE, AND DEPOSITION MASK MANUFACTURING METHOD

(71) Applicant: Sharp Kabushiki Kaisha, Sakai City, Osaka (JP)

(72) Inventors: MANABU NIBOSHI, Sakai City (JP); SHINICHI KAWATO, Sakai City (JP); YUHKI KOBAYASHI, Sakai City (JP); KAZUO TAKIZAWA, Sakai City (JP)

(73) Assignee: Sharp Kabushiki Kaisha, Sakai City, Osaka (JP)

(21) Appl. No.: 15/541,407

(22) PCT Filed: Dec. 28, 2015
(86) PCT No.: PCT/JP2015/086455

§ 371 Date: Jul. 3, 2017

(30) Foreign Application Priority Data
Jan. 5, 2015 (JP) 2015-000054

(51) Int. Cl. C23C 14/04; C23C 16/04; H01L 51/56

(52) U.S. Cl. CPC C23C 14/042; C23C 16/042; H01L 51/56

(57) ABSTRACT

The present invention is directed to a method for manufacturing a vapor deposition mask (2) which includes a mask section (3) and a mask frame (4). The mask section (3) includes an alloy containing iron and nickel. The method includes a heat treatment step of carrying out heat treatment with respect to the mask section (3) in a state in which end parts of the mask section (3) are fixed to the mask frame (4) while tension is applied to the mask section (3).

### TECHNICAL FIELD

The present invention relates to a vapor deposition mask and a method for manufacturing the vapor deposition mask.

### BACKGROUND ART

Recent years have witnessed practical use of a flat-panel display in various products and fields. This has led to a demand for a flat-panel display that is larger in size, that achieves higher image quality, and that consumes less power.

Under such circumstances, great attention has been drawn to an electroluminescent (hereinafter abbreviated to “EL”) display device that (i) includes an EL element which uses electroluminescence of an organic material or an inorganic material and that (ii) is an all-solid-state flat-panel display which is excellent in, for example, low-voltage driving, high-speed response, and self-emitting.

In order to achieve full-color display, the EL display device includes luminescent layers which correspond to respective of a plurality of sub-pixels constituting a pixel and respectively emit light of intended colors.

The luminescent layers are formed as vapor-deposited films by a vapor deposition step which is carried out with use of a fine metal mask (FMM) that serves as a vapor deposition mask and is provided with high-precision openings. In the vapor deposition step, the luminescent layers are formed by depositing different vapor deposition particles into different regions on a film formation target substrate.

In order to highly precisely deposit vapor deposition particles selectively in intended regions on the film formation target substrate, the vapor deposition mask is requested to have high accuracy in dimensions and to inhibit change in shape (thermal elongation) due to radiation heat during the vapor deposition.

In order to inhibit thermal elongation due to radiation heat during vapor deposition, conventionally, a vapor deposition mask has been used which is made of invar whose thermal expansion coefficient is small. Invar is considered to have a thermal expansion coefficient smaller than those of general metal materials because thermal shrinkage stress is caused by maximization of magnetic distortion between iron (Fe) and nickel (Ni).

Patent Literature 1 and Patent Literature 2 disclose a metal mask for vapor deposition which metal mask includes a pore-formed layer made of invar, a supporting layer made of invar, and a joining layer that is provided between the pore-formed layer and the supporting layer and is different in etching characteristic from the pore-formed layer and the supporting layer.

The metal mask of Patent Literature 1 and Patent Literature 2 contains invar and therefore has a small thermal expansion coefficient. This makes it possible to inhibit change in shape due to radiation heat during vapor deposition.

Further, in the metal mask of Patent Literature 1, crystals of invar used in the pore-formed layer and the supporting layer are oriented such that a degree of orientation in a main orientation (200) among main orientations (111), (200), (311), and (220) becomes 60% to 99%. This makes it possible to improve an etching rate for forming openings, and this improves productivity.

### CITATION LIST

### Patent Literature

[Patent Literature 1]

Japanese Patent No. 3975439 (Registration Date: Jun. 29, 2007)

[Patent Literature 2]

Japanese Patent No. 4126648 (Registration Date: May 23, 2008)

### Non-Patent Literature

[Non-Patent Literature 1]

NAKAMA Kazuo, four others, “Effects of Cold-Drawing and Annealing Condition on Thermal Expansion of Fe-36 mass % Ni Alloy”, Journal of the Japan Institute of Metals and Materials, Vol. 77, No. 11, (2013), 537-542

### SUMMARY OF INVENTION

### Technical Problem

However, a thermal expansion coefficient of invar is 9 to 13×10⁻⁶/° C. in a form of a plate with thickness of 12 mm, and is 1×10⁻⁶/° C. (3 mmφ×10 mmt) in a form of cylindrical bulk material. As such, the thermal expansion coefficient of invar varies depending on shapes.

Moreover, in a case where vapor deposition is carried out with use of the metal mask of Patent Literature 1, the vapor deposition is carried out in a state in which the metal mask to which tension is applied is attached to a mask frame in order to prevent the metal mask from being bent. However, for example, in a metal mask having a form of thin foil (e.g., with a thickness of 50 μm), crystallographic orientations of crystals constituting invar contained in the metal mask become anisotropic by adding tension or rolling, and magnetic directions become uniform. As a result, directions of thermal shrinkage of invar become uniform, and therefore the thermal expansion coefficient of the metal mask increases.

As such, the thermal expansion coefficient of the metal mask changes due to influence of processing carried out before an end use state in the vapor deposition step, and therefore original physical properties of invar are not directly reflected.

Therefore, in an actual vapor deposition step, even in a case where a radiation heat is, for example, lower than 100° C., the metal mask may be elongated by heat and accuracy of positions of vapor-deposited films to be formed by selective vapor deposition may decrease.

Patent Literature 1 does not take into consideration the increase in thermal expansion coefficient that is caused by applying tension to the metal mask when the metal mask is fixed to the mask frame after openings are provided in the metal mask by wet processing. That is, Patent Literature 1 does not take into consideration the thermal expansion coefficient of the metal mask in the state of being tensioned and fixed to the mask frame.

In the metal mask used in the vapor deposition step, anisotropy of crystallographic orientations is enhanced by fixing the metal mask, to which tension is being applied, to the mask frame, and the thermal expansion coefficient is greater than before the tension is applied to the metal mask. Therefore, with the conventional metal mask, it is difficult to provide a highly precise vapor deposition pattern.

The present invention is accomplished in view of the problem, and its object is to provide a vapor deposition mask, a vapor deposition device, and a method for manufacturing the vapor deposition mask, each of which can achieve a highly precise vapor deposition pattern.

### Solution to Problem

In order to attain the object, the method in accordance with an aspect of the present invention is a method for manufacturing a vapor deposition mask which includes a mask section and a mask frame, the mask section being provided with an opening for forming a film of a vapor deposition material on a film formation target substrate, and the mask section including an alloy containing iron and nickel, the method including: a heat treatment step of carrying out heat treatment with respect to the mask section in a state in which end parts of the mask section are fixed to the mask frame while tension is applied to the mask section.

In order to attain the object, the vapor deposition mask in accordance with an aspect of the present invention includes: a mask section which is provided with an opening for forming a film of a vapor deposition material on a film formation target substrate; and a mask frame, end parts of the mask section being fixed to the mask frame in a state in which tension is applied to the mask section, the mask section including an alloy containing iron and nickel, and crystals constituting the alloy being isotropically oriented.

### Advantageous Effects of Invention

According to an aspect of the present invention, it is possible to provide the vapor deposition mask and the method for manufacturing the vapor deposition mask which has a small thermal expansion coefficient and can achieve a highly precise vapor deposition pattern.

### BRIEF DESCRIPTION OF DRAWINGS

FIG. 1 is a cross-sectional view illustrating a configuration of main parts of a vapor deposition device in accordance with Embodiment 1 of the present invention.

FIG. 2 is an X-ray diffraction spectrum at a diffraction angle of invar disclosed in Non-Patent Literature 1.

FIG. 3 is a graph showing influence on an average thermal expansion coefficient by an annealing temperature of invar disclosed in Non-Patent Literature 1.

(a) through (e) of FIG. 4 are cross-sectional views sequentially illustrating processes for manufacturing the vapor deposition mask in accordance with Embodiment 1 of the present invention.

(a) of FIG. 5 is a view illustrating change in crystal orientations of crystal grains of invar by tensioned welding, and (b) of FIG. 5 is a view illustrating change in crystal orientations of crystal grains of invar by heat baking.

FIG. 6 is a cross-sectional view illustrating a configuration of main parts of a vapor deposition device in accordance with Embodiment 2 of the present invention.

(a) through (d) of FIG. 7 are cross-sectional views sequentially illustrating processes for manufacturing the vapor deposition mask in accordance with Embodiment 2 of the present invention.

FIG. 8 is a cross-sectional view illustrating a configuration of main parts of a vapor deposition device in accordance with Embodiment 3 of the present invention.

(a) through (e) of FIG. 9 are cross-sectional views sequentially illustrating processes for manufacturing the vapor deposition mask in accordance with Embodiment 3 of the present invention.

### DESCRIPTION OF EMBODIMENTS

### Embodiment 1

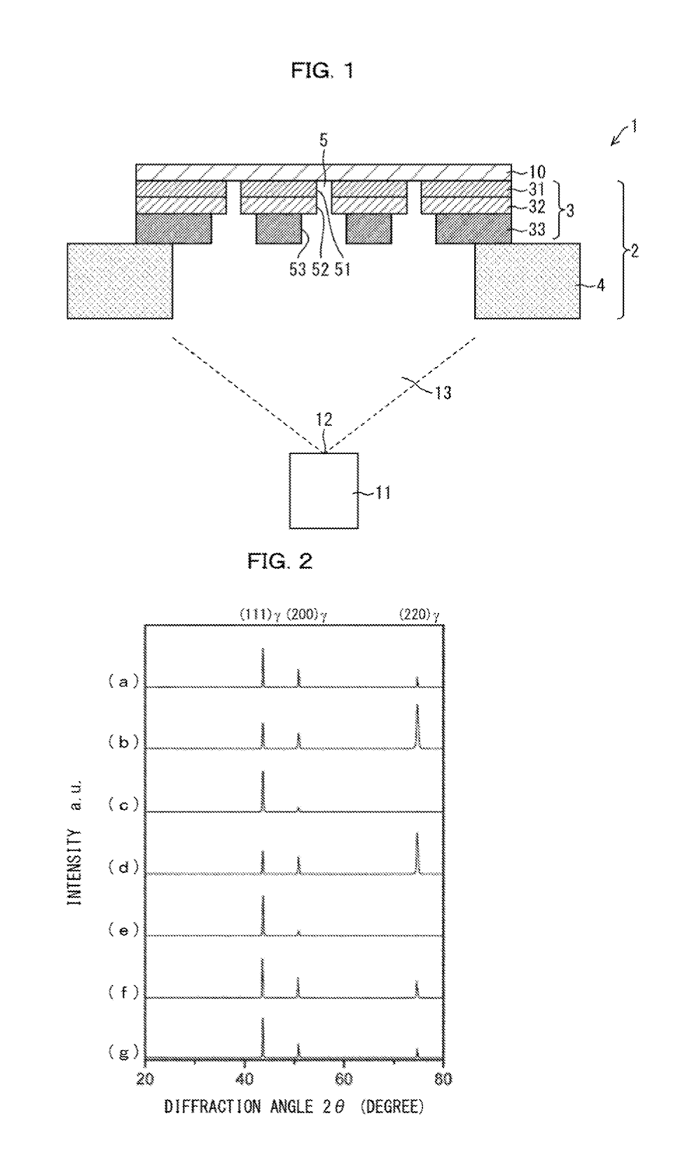

The following description will discuss an embodiment of the present invention with reference to FIG. 1 through (a) and (b) of FIG. 5.

<Vapor Deposition Device>

FIG. 1 is a cross-sectional view illustrating a configuration of main parts of a vapor deposition device 1 in accordance with Embodiment 1.

The vapor deposition device 1 is a device for forming a vapor-deposited film from a vapor deposition material in a film formation area of a film formation target substrate 10. The vapor deposition device 1 can form, for example, a luminescent layer of an EL display device as the vapor-deposited film.

As illustrated in FIG. 1, the vapor deposition device 1 includes a vapor deposition mask 2 and a vapor deposition source 11 for depositing a vapor deposition material onto the film formation target substrate 10 via the vapor deposition mask 2.

The vapor deposition mask 2 includes a mask section 3 which has a parallel plate shape and a mask frame 4 which holds end parts of the mask section 3. The mask section 3 is provided with at least one opening 5. The opening 5 has a shape which (i) is identical (or substantially identical) with that of a vapor-deposited film pattern that is formed on a surface of the film formation target substrate 10 or (ii) corresponds to at least part of the vapor-deposited film pattern. For example, a plurality of openings 5 are provided in the mask section 3. In a plan view, each of the plurality of openings 5 has a rectangular shape and the plurality of openings 5 are arranged in a matrix manner.

The mask frame 4 has a frame shape in which an opening is provided in a center. The end parts (peripheral edges) of the mask section 3 are fixed to the mask frame 4 in a state in which tension is applied in a direction parallel to a surface of the mask section 3.

The vapor deposition mask 2 is a mask for forming a vapor-deposited film at an intended position on the film formation target substrate 10, and is arranged so as to face the film formation target substrate 10 during vapor deposition.

The vapor deposition source 11 is arranged across the vapor deposition mask 2 from the film formation target substrate 10 so as to face the vapor deposition mask 2. The vapor deposition source 11 is a container which contains the vapor deposition material inside. Note that the vapor deposition source 11 can be a container which directly contains the vapor deposition material inside or can be configured to have a load-lock pipe so that the vapor deposition material is externally supplied.

The vapor deposition source 11 has an injection hole 12 which is provided on an upper surface (facing the vapor deposition mask 2) side of the vapor deposition source 11 for injecting a vapor deposition material as vapor deposition particles 13.

The vapor deposition source 11 generates the vapor deposition particles 13 in a form of gas by evaporating the vapor deposition material (in a case where the vapor deposition material is a liquid material) or sublimating the vapor deposition material (in a case where the vapor deposition material is a solid material) with heat. The vapor deposition source 11 emits, as the vapor deposition particles 13, the gaseous vapor deposition material toward the vapor deposition mask 2 from the injection hole 12.

In the vapor deposition method (vapor deposition step) using the vapor deposition device 1, for example, the vapor deposition mask 2 and the film formation target substrate 10 are arranged so as to face each other, and the vapor deposition material is deposited onto the film formation target substrate 10 via the opening 5 in the vapor deposition mask 2 while the vapor deposition mask 2 and the film formation target substrate 10 are adhered (i.e., contacting) to each other as illustrated in FIG. 1. From this, a vapor-deposited film in a predetermined pattern can be formed in the film formation area on the film formation target substrate 10.

Note, however, that the vapor deposition method using the vapor deposition device 1 is not limited to fixed vapor deposition in which vapor deposition is carried out while the vapor deposition mask 2 and the film formation target substrate 10 are fixed in the contacting state.

In the vapor deposition step using the vapor deposition device 1, it is possible to carry out scan vapor deposition by relatively moving the vapor deposition mask and the film formation target substrate 10, or it is possible to carry out step vapor deposition in which vapor deposition is carried out once while aligning the vapor deposition mask 2 and the film formation target substrate 10 and then vapor deposition is carried out again while changing a position of the vapor deposition mask 2 with respect to the film formation target substrate 10.

In the above description, as an example, the openings 5 are arranged in a matrix manner (i.e., two-dimensionally arranged). Note, however, that a shape and an arrangement of the openings 5 are not limited to the above described ones and can be set as appropriate in accordance with a purpose of use (that varies depending on a type of the vapor-deposited film), a vapor deposition method, and the like such that an intended vapor-deposited film pattern can be obtained.

The opening 5 can have a shape of, for example, a slit or a slot in a plan view. Moreover, it is only necessary to provide at least one opening 5, and the opening 5 can be arranged only in one-dimensional direction in a plan view, and it is possible to provide only one opening 5.

<Vapor Deposition Mask>

The mask section 3 of the vapor deposition mask 2 has a three-layer structure in which a pore-formed layer 31, a joining layer 32, and a supporting layer 33 are stacked in this order.

The pore-formed layer 31 is provided with a through hole 51 (first through hole), the joining layer 32 is provided with a through hole 52, and the supporting layer 33 is provided with a through hole 53 (second through hole). The through hole 51, the through hole 52, and the through hole 53 constitute an opening 5 which is a through hole passing through from a front surface to a rear surface of the mask section 3. An opening width of the through hole 51 is smaller than that of the through hole 53, and an opening width of the opening 5 in the mask section 3 is defined by the opening width of the through hole 51.

The pore-formed layer 31 constitutes a surface which makes contact with the film formation target substrate 10 in the vapor deposition step, and the supporting layer 33 constitutes a surface which faces the vapor deposition source 11. In order to reduce influence of a vapor deposition shadow, the pore-formed layer 31 is preferably thin and is, for example, set to have a thickness of 10 μm or less.

The supporting layer 33 is thicker than the pore-formed layer 31, and supports the pore-formed layer 31 so as to prevent the pore-formed layer 31 from bending. By providing the supporting layer 33, it is possible to inhibit bending of the entire mask section 3. In order to inhibit bending of the mask section 3, the supporting layer 33 is preferably thick, and the through hole 53 provided in the supporting layer 33 is preferably small. Meanwhile, in order to reduce influence by a vapor deposition shadow, the supporting layer 33 is preferably thin, and the opening width of the through hole 53 is preferably large.

A thickness of the supporting layer 33 is preferably equivalent to or less than a smallest length of the opening 5 and is set to, for example, approximately 30 μm to 100 μm.

Thicknesses of the pore-formed layer 31 and the supporting layer 33 and sizes of the through holes provided in the pore-formed layer 31 and the supporting layer 33 are preferably determined while taking into consideration bending that can be caused depending on a size of the mask section 3 and a vapor deposition shadow that can be caused depending on designs of the vapor deposition source 11 and the injection hole 12.

Each of the pore-formed layer 31 and the supporting layer 33 is made of an alloy containing iron (Fe) and nickel (Ni). The alloy containing iron and nickel can be invar (invar alloy) or kovar (kovar alloy).

Invar is an alloy in which 36% to 50% of nickel is mixed with iron (Fe-36% Ni to Fe-50% Ni), and contains, for example, manganese (Mn) and carbon (C) as trace components. Note that invar in which 36% of nickel is added to iron (Fe-36% Ni) is particularly known to have a small thermal expansion coefficient.

Kovar is an alloy in which, for example, 29% of nickel and 17% of cobalt (Co) are mixed with iron (29Ni-17Co—Fe), and contains, for example, manganese and silicon (Si) as trace components.

By forming each of the pore-formed layer 31 and the supporting layer 33 with use of an alloy such as invar or kovar which contains iron and nickel and has a small thermal expansion coefficient, it is possible to inhibit deformation of the mask section 3 by radiation heat during vapor deposition.

Moreover, in a case where (i) each of the pore-formed layer 31 and the supporting layer 33 is formed with use of a magnetic substance such as invar and (ii) a magnet is provided on a rear surface of the film formation target substrate 10, it is possible to cause the vapor deposition mask 2 to more surely adhere to the film formation target substrate 10 with magnetic force.

Note that, instead of invar and kovar, it is possible to form the pore-formed layer 31 and the supporting layer 33 with use of an alloy containing iron and platinum (Pt) (Fe—Pt alloy) or an alloy containing iron and palladium (Pd) (Fe—Pd alloy).

The joining layer 32 is a layer for joining the pore-formed layer 31 to the supporting layer 33. The joining layer 32 preferably has a melting point lower than that of iron and has sufficient chemical stability. As such a material, it is possible to use titanium (Ti), gold (Au), silver (Ag), copper (Cu), or the like.

The joining layer 32 can be made of a material which has an etching characteristic different from that of a material constituting the pore-formed layer 31 and the supporting layer 33. As such a material, for example, it is possible to use tin (Sn), silver (Ag), or the like. According to the configuration, in a step of forming the through hole 53 in the supporting layer 33 by etching, it is possible to prevent a through hole from being formed in the pore-formed layer 31, and it is thus possible to form the through hole 53 in the supporting layer 33 and the through hole 51 in the pore-formed layer 31 with separate steps. From this, it is possible to provide through holes which have different sizes in the respective layers.

Note that it is only needs to secure the thickness of the joining layer 32 which thickness is necessary as an etching barrier, and it is enough to set the thickness to approximately 1 μm.

The mask section 3 is fixed, in a state in which the mask section 3 is sufficiently tensioned, to the mask frame 4 by, for example, welding peripheral edges of the mask section 3 to the mask frame 4 with laser light or by causing the mask section 3 to adhere to the mask frame 4 with another method such as applying an adhesive agent. This makes it possible to inhibit bending of the mask section 3, and it is therefore possible to inhibit floating of the mask section 3 from the film formation target substrate 10 during vapor deposition.

<Crystal Orientation of Mask Section>

In the vapor deposition mask 2, crystals constituting the pore-formed layer 31 and the supporting layer 33 in the mask section 3 are isotropically oriented.

For example, in a case where each of the pore-formed layer 31 and the supporting layer 33 is made of invar, crystals constituting invar contained in the pore-formed layer 31 and the supporting layer 33 are oriented such that crystal faces become (111), (200), (220), and (311), and degrees of orientation of all of the crystal faces are equal to or lower than 60%. In particular, a degree of orientation to (200) is 50% or lower.

Here, the degree of orientation of crystal face indicates a ratio of the number of crystals which are oriented along that crystal face, among the total number of crystals constituting invar.

From this, directions of thermal shrinkage of invar become isotropic, and it is consequently possible to decrease a thermal expansion coefficient as described later. As such, it is possible to inhibit thermal elongation of the mask section 3 (or the vapor deposition mask 2) in the vapor deposition step, and this makes it possible to provide a highly precise vapor deposition pattern.

<Crystallographic Orientation of Invar>

The following description will discuss a crystallographic orientation of invar, with reference to Non-Patent Literature 1. FIG. 2 shows X-ray diffraction spectrums of invar disclosed in Non-Patent Literature 1.

A spectrum of (a) of FIG. 2 is an X-ray diffraction spectrum of a solution treatment material that has been obtained by forging an ingot of 50 kg of invar at 1150° C. into a bar with a diameter of 40 mm, then maintaining the bar at 1000° C. for 30 minutes, and then cooling the bar with water.

A spectrum of (b) of FIG. 2 is an X-ray diffraction spectrum of a surface, in a direction parallel to a drawing direction, of a drawn material which has been obtained by lathing the solution treatment material of invar into a bar with a diameter of 38 mm, and then processing the bar by cold drawing so that the bar has a diameter of 27 mm.

A spectrum of (c) of FIG. 2 is an X-ray diffraction spectrum of a surface, in a direction parallel to a radial direction, of a drawn material which has been obtained by lathing the solution treatment material of invar into a bar with a diameter of 38 mm, and then processing the bar by cold drawing so that the bar has a diameter of 27 mm.

A spectrum of (d) of FIG. 2 is an X-ray diffraction spectrum of a surface, in the direction parallel to the drawing direction, of a drawn material which has been obtained by annealing the drawn material at 550° C. for 2 hours.

A spectrum of (e) of FIG. 2 is an X-ray diffraction spectrum of a surface, in the direction parallel to the radial direction, of a drawn material which has been obtained by annealing the drawn material at 550° C. for 2 hours.

A spectrum of (f) of FIG. 2 is an X-ray diffraction spectrum of a surface, in the direction parallel to the drawing direction, of a drawn material which has been obtained by annealing the drawn material at 650° C. for 2 hours.

A spectrum of (g) of FIG. 2 is an X-ray diffraction spectrum of a surface, in the direction parallel to the radial direction, of a drawn material which has been obtained by annealing the drawn material at 650° C. for 2 hours.

As shown in (a) of FIG. 2, in the solution treatment material, a diffraction peak from the (111) face is highest, and crystallographic orientations are approximately isotropic.

As shown in (b) of FIG. 2, a diffraction peak of the drawn material is higher from the (220) face than from the (111) face and the (200) face, in the face that is parallel to the drawing direction. Meanwhile, as shown in (c) of FIG. 2, a diffraction peak of the drawn material from the (220) face is extremely small, and a diffraction peak of the drawn material from the (111) face is highest, in the face that is parallel to the radial direction. From these, it is shown that anisotropy of crystallographic orientations is caused by the drawing treatment, and a texture having a (011) face in a cross section that is parallel to the drawing direction and a texture that is drawn in a direction including a <011> direction are developed.

Moreover, as shown in (d) of FIG. 2, a diffraction peak of the drawn material, which has been subjected to annealing at 550° C. for 2 hours, is higher from the (220) face than from the (111) face and the (200) face, in the face that is parallel to the drawing direction. Meanwhile, as shown in (e) of FIG. 2, a diffraction peak of the drawn material, which has been subjected to annealing at 550° C. for 2 hours, from the (220) face is extremely small, and a diffraction peak of the drawn material from the (111) face is highest, in the face that is parallel to the radial direction. From these, it is shown that anisotropy of crystallographic orientations caused by the drawing treatment is maintained even after the annealing at 550° C. has been carried out for 2 hours.

Moreover, as shown in (f) and (g) of FIG. 2, a diffraction peak of the drawn material, which has been subjected to annealing at 650° C. for 2 hours, from the (220) face is low and is equivalent to a spectrum of the solution treatment material, in the face that is parallel to the drawing direction and in the face that is parallel to the radial direction. This shows that isotropy of crystallographic orientations of the drawn material has been enhanced by the annealing at 650° C. for 2 hours. Note that recrystallization of invar starts at 650° C., and therefore recrystallization starts by the annealing at 650° C. for 2 hours, and thus new crystal grains are generated, and consequently isotropy of crystallographic orientations is enhanced.

The above characteristic is common to various compositions of invar. Further, alloys (such as kovar) which contain iron and nickel also have a characteristic similar to the above described characteristic of invar.

<Thermal Expansion Coefficient of Invar>

The following description will discuss, with reference to Non-Patent Literature 1, influence of an annealing temperature of invar on an average thermal expansion coefficient.

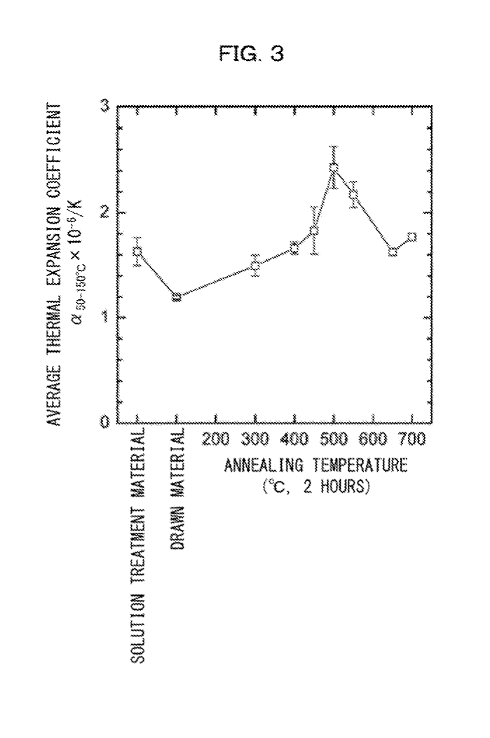

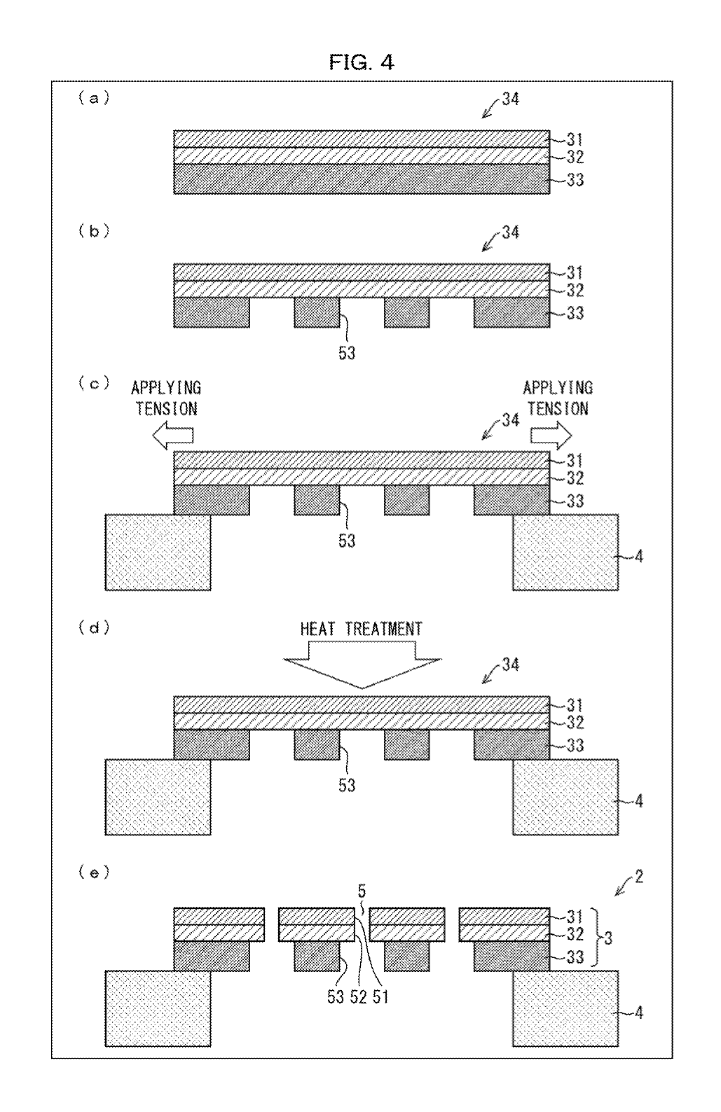

FIG. 3 is a graph showing influence of an annealing temperature of invar on an average thermal expansion coefficient, which is disclosed in Non-Patent Literature 1. In FIG. 3, a vertical axis represents an average thermal expansion coefficient obtained in a case where a temperature of the solution treatment material and the drawn material of invar described with reference to FIG. 2 is changed from 50° C. to 150° C.

As shown in FIG. 3, an average thermal expansion coefficient of the solution treatment material is approximately 1.6×10⁻⁶/° C. Meanwhile, an average thermal expansion coefficient of the drawn material is approximately 1.2×10⁻⁶/° C. This shows that, in a case where invar in a state of a solid bar (bulk) such as a bar is used as a test piece, a thermal expansion coefficient of the test piece decreases by subjecting the test piece to the drawing treatment.

However, in a case where the test piece is a thin foil or a foil sample (in a form of foil), the thermal expansion coefficient of the test piece increases by rolling or stretching. Specifically, in a case where the test piece is an invar foil, it is known that the average thermal expansion coefficient increases up to 9 to 13×10⁻⁶/° C. This seems to be because, in a case where the test piece is thin, anisotropy of crystallographic orientations increases due to decrease in degree of freedom of crystal orientation in a thickness direction, and a thermal shrinkage effect of invar is reduced, and therefore the thermal expansion coefficient increases. From this, in a case of thin invar having a thickness of approximately 10 μm to 50 μm as each of the layers in the mask section 3 of the vapor deposition mask 2, the thermal expansion coefficient increases by rolling or stretching.

Moreover, as shown in FIG. 3, the average thermal expansion coefficient of invar after annealing at 500° C. for 2 hours is approximately 2.5×10⁻⁶/° C., which is larger than the average thermal expansion coefficient of the solution treatment material. Meanwhile, the average thermal expansion coefficient of invar after annealing at 650° C. for 2 hours is approximately 1.6×10⁻⁶/° C.

From this, by setting the annealing temperature to 650° C., it is possible to effectively reduce the average thermal expansion coefficient of invar. Moreover, considering the crystallographic orientation of invar described with reference to FIG. 2 together, it seems that isotropy of crystal orientations (crystallographic orientations) of invar increases by annealing at 650° C., and accordingly the average thermal expansion coefficient decreases.

The above characteristic is common to various compositions of invar. Further, alloys (such as kovar) which contain iron and nickel also have a characteristic similar to the above described characteristic of invar.

As above described, in the vapor deposition mask 2 of Embodiment 1, crystals constituting the pore-formed layer 31 and the supporting layer 33 in the mask section 3 are isotropically oriented. Therefore, the thermal expansion coefficient of the vapor deposition mask 2 is low and it is possible to inhibit thermal elongation of the mask section 3 (or the vapor deposition mask 2) in the vapor deposition step, and this makes it possible to provide a highly precise vapor deposition pattern.

<Method for Manufacturing Vapor Deposition Mask>

The following description will discuss a method for manufacturing the vapor deposition mask 2 with reference to (a) through (d) of FIG. 4. (a) through (d) of FIG. 4 are cross-sectional views sequentially illustrating processes for manufacturing the vapor deposition mask 2 in accordance with Embodiment 1.

The followings describe a method for manufacturing the vapor deposition mask 2 in which each of the pore-formed layer 31 and the supporting layer 33 is formed with use of invar and the joining layer 32 is formed with use of titanium.

In the manufacturing processes of the vapor deposition mask 2, first, as illustrated in (a) of FIG. 4, a board 34 is prepared which is to constitute the mask section 3. The board 34 is in a cut-sheet form having a three-layer structure in which the pore-formed layer 31, the joining layer 32, and the supporting layer 33 are stacked in this order.

For example, it is possible that a thickness of the pore-formed layer 31 is 10 μm, a thickness of the joining layer 32 is 1 μm, and a thickness of the supporting layer is 50 μm. Moreover, crystals constituting the pore-formed layer 31 and the supporting layer 33 in the board 34 are preferably isotropically oriented.

Next, as illustrated in (b) of FIG. 4, a through hole 53 (second through hole) is formed in the supporting layer 33 by etching (wet processing). Each of the supporting layer 33 and the pore-formed layer 31 is made of invar, and the joining layer 32 which is made of titanium is provided between the supporting layer 33 and the pore-formed layer 31. With this arrangement, it is possible to form the through hole 53 only in the supporting layer 33 without forming a through hole in the pore-formed layer 31 and the joining layer 32. Note that the thickness of the joining layer 32 is preferably small, to an extent that the joining layer 32 can prevent, by chemically protecting the pore-formed layer 31, a through hole from being formed in the pore-formed layer 31 during the etching step carried out with respect to the supporting layer 33.

Next, as illustrated in (c) of FIG. 4, end parts of the board 34 are fixed to the mask frame 4 while the board 34 is tensioned, i.e., tension is applied to the board 34 (tensioned fixing). For example, the end parts of the board 34 can be fixed to the mask frame 4 by welding (tensioned welding).

Next, as illustrated in (d) of FIG. 4, heat treatment (annealing/heating/cooling) is carried out with respect to the board 34 which has been tensioned and fixed to the mask frame 4 (heat treatment step). Specifically, heat baking is carried out by heat at 650° C. or higher in an inert atmosphere, and then the board 34 is cooled.

Note that, conventionally, a vapor deposition mask has been manufactured by processing a thin steel sheet while transferring the thin steel sheet by roll transfer or line transfer. Therefore, in the conventional manufacturing process of the vapor deposition mask, a shape before heating cannot be maintained if the thin steel sheet is processed by heat at a temperature equal to or higher than a softening temperature. Specifically, in a case where the thin steel sheet is processed by heat during roll transfer, the thin steel sheet is softened and tension is loosened. Alternatively, in a case where the thin steel sheet is processed by heat during line transfer, the thin steel sheet is softened and an undulation occurs in the thin steel sheet. As a result, a problem occurs that a transferring speed during the transfer becomes nonuniform, and a shape (thickness) of a manufactured vapor deposition mask becomes nonuniform.

In Embodiment 1, during heat treatment, the board 34 which is tensioned and fixed to the mask frame 4 is subjected to heat baking at 650° C., and consequently the board 34 is softened. This seems to be mainly because an Ni component exceeds the Curie point and a magnetic balance is lost, and this causes a sharp increase in thermal expansion coefficient. However, in Embodiment 1, the board 34 is cooled, after heat baking, in a state in which the board 34 is fixed to the mask frame 4 and the shape of the board 34 is maintained, and it is therefore possible to maintain the shape before heating even after the board 34 is heated in the heat treatment as described above at a temperature equal to or higher than the softening temperature.

(a) of FIG. 5 is a view illustrating change in crystal orientations of crystal grains of invar by tensioned welding, and (b) of FIG. 5 is a view illustrating change in crystal orientations of crystal grains of invar by heat baking. In (a) and (b) of FIG. 5, each of solid line arrows indicates a surface orientation of a crystal face 7 of each crystal grain 6, and each of dashed-line arrows indicates a crystallographic orientation along which the crystal faces 7 are aligned.

In a case where tension is applied to the board 34, a degree of freedom of crystals which constitute the board 34 becomes smaller in the thickness direction. As a result, as shown in the state after rolling/tensioned welding illustrated in (a) of FIG. 5, crystallographic orientations of the crystal grains 6 become uniform, and thus crystallographic orientations become anisotropic. In a case where the crystallographic orientations become anisotropic, the thermal expansion coefficient increases.

However, in a case where the heat treatment step is carried out in which the board 34 is subjected to heat treatment in a state in which tension is applied to the board 34 and the end parts of the board 34 are fixed to the mask frame 4, crystallographic orientations of crystals constituting invar contained in the mask section 3 become isotropic as shown in the state after heat baking illustrated in (b) of FIG. 5. In a case where the crystallographic orientations of crystals constituting invar become isotropic, the thermal expansion coefficient of the mask section 3 decreases.

Note that, in a case where the board 34 is subjected to heat baking, it is preferable that the board 34 is subjected to heat baking in a state in which the board 34 is placed on a heat resistant supporting base such as an SUS material or a quartz plate. This makes it possible to inhibit change in shape that is caused due to softening of the board 34 during heat baking of the board 34.

Next, as illustrated in (e) of FIG. 4, a through hole 51 (first through hole) is formed in the pore-formed layer 31 by laser processing, and a through hole 52 is formed in the joining layer 32 (opening forming step). The through hole 51, the through hole 52, and the through hole 53 constitute a through hole (opening 5) in the mask section 3.

With those steps, it is possible to manufacture the vapor deposition mask 2 that is made up of the mask section 3 and the mask frame 4. By carrying out laser processing, it is possible to form the through hole 51 and the through hole 52 in the pore-formed layer 31 made of invar and the joining layer 32 made of titanium, respectively, with a single step. Moreover a laser used in the laser processing is preferably an ultrashort pulse laser. In a case where an alloy such as invar having high heat conductivity is subjected to laser processing with use of the ultrashort pulse laser, it is possible to form a through hole with high accuracy of dimensions, as compared with a case where laser processing is carried out with use of a normal continuous wave laser.

Opening widths of the through hole 51 and the through hole 52 are smaller than the opening width of the through hole 53. With the configuration, an opening width of the opening 5 in the vapor deposition mask 2 is not defined by the through hole 53 but is defined by the through hole 51. Therefore, the opening width of the through hole 53 formed by the etching step illustrated in (b) of FIG. 4 causes small influence on accuracy of the vapor deposition pattern.

In a conventional method for manufacturing a vapor deposition mask, a thin invar foil is rolled (or stretched), an opening is formed in the foil by chemical etching, and then the foil is attached and welded to a mask frame. A magnetic balance of the foil largely changes through mechanical treatment and chemical treatment. In particular, through the mechanical treatment, crystal grains in invar are drawn in a particular direction, and therefore crystallographic orientations become uniform in a particular direction and a magnetic fluctuation decreases. As a result, a thermal shrinkage stress decreases and a thermal expansion coefficient increases.

On the other hand, the method for manufacturing the vapor deposition mask 2 in accordance with Embodiment 1 includes the heat treatment step of carrying out heat treatment with respect to the board 34 in a state in which tension is applied to the board 34 (mask section 3) made of an alloy such as invar and the end parts of the board 34 are fixed to the mask frame 4.

From this, (i) the vapor deposition mask 2 manufactured by the method has a small thermal expansion coefficient, (ii) it is possible to inhibit thermal expansion during the vapor deposition step, and (iii) it is possible to provide a highly precise vapor deposition pattern.

That is, the mask section 3 in the state (i.e., end use state) of being usable as the vapor deposition mask 2 has a thermal expansion coefficient which is smaller than that of a mask section of a conventional vapor deposition mask. From this, by carrying out vapor deposition with use of the vapor deposition mask 2 of Embodiment 1, it is possible to provide a highly precise vapor deposition pattern.

Moreover, in Embodiment 1, the end parts of the board 34 are fixed to the mask frame 4 while tension is applied to the board 34, and then the through holes 51 and 52 are formed in the pore-formed layer 31 and the joining layer 32, respectively, by laser processing. Therefore, according to Embodiment 1, it is possible to improve accuracy of dimensions and accuracy of positions of the pore-formed layer 31 and the joining layer 32 which define dimensions of the opening 5, as compared with a case where vapor deposition is carried out while a metal mask, which is disclosed in Patent Literatures 1 and 2 and is provided with an opening, is attached to a mask frame with tension in order to prevent bending of the metal mask.

<Modification Example>

In the descriptions above, the through hole 51 and the through hole 52 are formed by laser processing after the board 34 is subjected to heat baking. Note, however, that the method for manufacturing the vapor deposition mask 2 of Embodiment 1 is not limited to this, provided that at least the board 34 is subjected to heat treatment as illustrated in (d) of FIG. 4 after the board 34 is fixed to the mask frame 4 with tension as illustrated in (c) of FIG. 4.

Therefore, for example, in the processes of manufacturing the vapor deposition mask 2, it is possible to invert an order of the heat treatment step illustrated in (d) of FIG. 4 and the opening forming step illustrated in (e) of FIG. 4. That is, it is possible to carry out the heat treatment with respect to the board 34 as illustrated in (d) of FIG. 4 after the through hole 51 and the through hole 52 are formed by laser processing as illustrated in (e) of FIG. 4.

Even the modification example described above includes the heat treatment step of carrying out heat treatment with respect to the board 34 in a state in which the end parts of the board 34 are fixed to the mask frame 4 while tension is applied to the board 34. Moreover, in the present modification example also, the through holes 51 and 52 are formed in the pore-formed layer 31 and the joining layer 32, respectively, by laser processing after the end parts of the board 34 are fixed to the mask frame 4 while tension is applied to the board 34. The present modification example can also bring about an effect similar to the above described effect.

### Embodiment 2

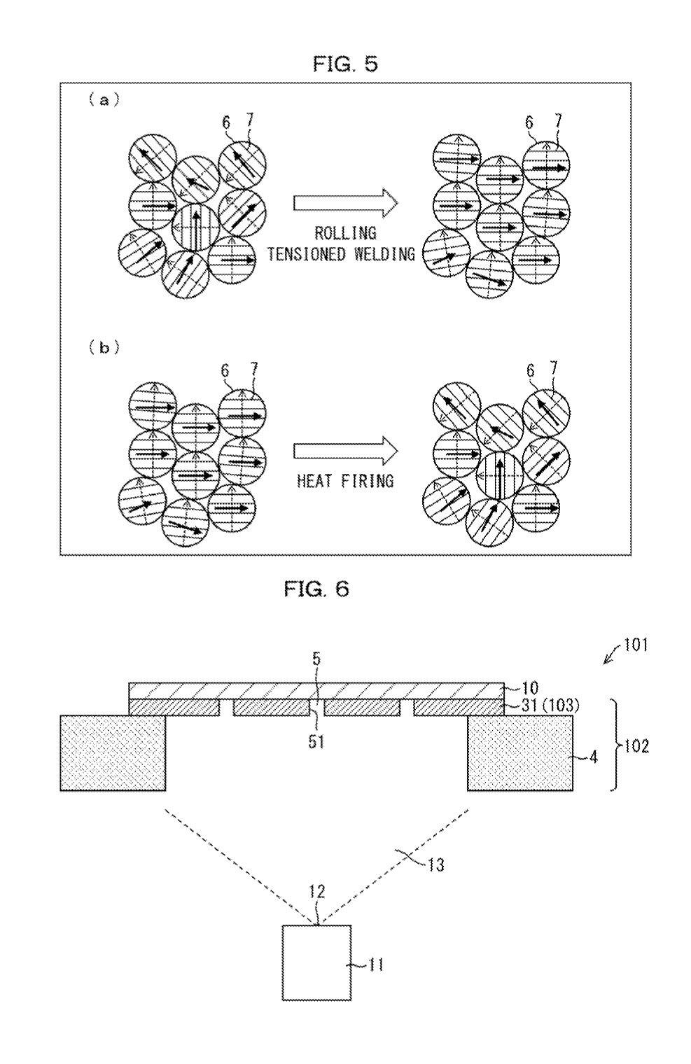

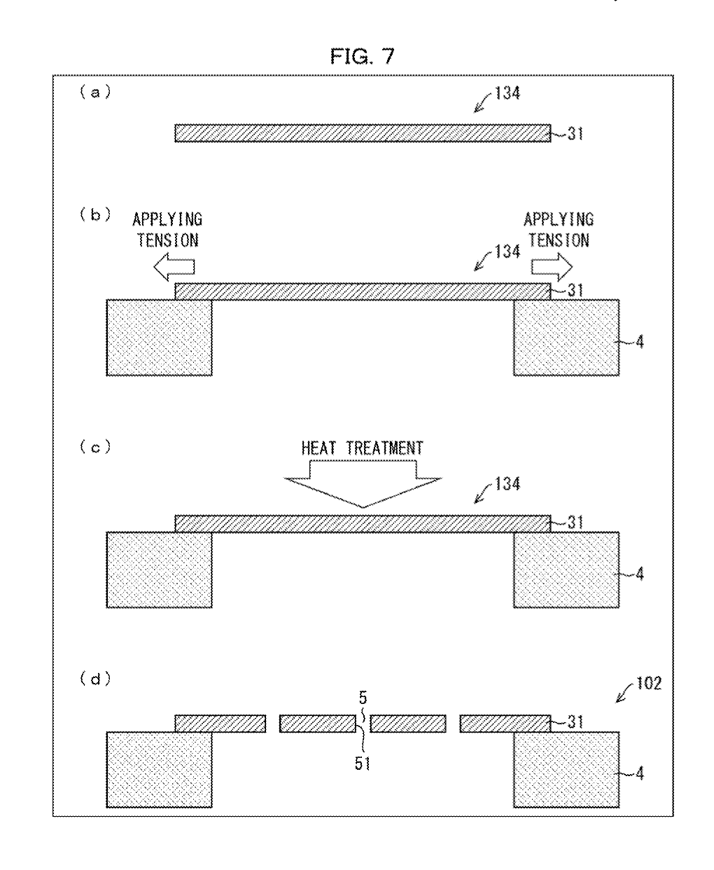

The following description will discuss another embodiment of the present invention with reference to FIG. 6 and (a) through (d) of FIG. 7. Note that, for convenience of explanation, identical reference numerals are given to constituent members having functions identical with those of the constituent members described in the above Embodiment 1, and descriptions of such constituent members are omitted here.

FIG. 6 is a cross-sectional view illustrating a configuration of main parts of a vapor deposition device 101 in accordance with Embodiment 2.

As illustrated in FIG. 6, the vapor deposition device 101 has a configuration substantially identical with that of the vapor deposition device 1 in accordance with Embodiment 1, except that a mask section 103 in a vapor deposition mask 102 has a single-layer structure made up of a pore-formed layer 31.

In the vapor deposition mask 102, an opening 5 which is a through hole passing through from a front surface to a rear surface of the mask section 103 is constituted by the through hole 51.

As with the mask section 3 of the vapor deposition mask 2 in accordance with Embodiment 1, crystals constituting an alloy contained in the mask section 103 are isotropically oriented.

Unlike the vapor deposition mask 2 of Embodiment 1, in the vapor deposition mask 102, the supporting layer 33 and the joining layer 32 are not provided in the mask section 103. Therefore, it is possible to reduce a thickness of the mask section 103, as compared with the mask section 3 of the vapor deposition mask 2. With the configuration, it is possible to reduce influence of a vapor deposition shadow.

<Method for Manufacturing Vapor Deposition Mask>

The following description will discuss a method for manufacturing the vapor deposition mask 102 with reference to FIG. 7. (a) through (c) of FIG. 7 are cross-sectional views sequentially illustrating processes for manufacturing the vapor deposition mask 102 in accordance with Embodiment 2.

The followings describe a method for manufacturing the vapor deposition mask 102 in which the pore-formed layer 31 is formed with use of invar.

In the processes for manufacturing the vapor deposition mask 102, first, as illustrated in (a) of FIG. 7, a board 134 is prepared which is to constitute the mask section 103. The board 134 is in a cut-sheet form having a single-layer structure including the pore-formed layer 31.

Next, as illustrated in (b) of FIG. 7, end parts of the board 134 are fixed to the mask frame 4 while the board 134 is tensioned, i.e., tension is applied to the board 134 (tensioned fixing). For example, the end parts of the board 134 can be fixed to the mask frame 4 by welding (tensioned welding).

Next, as illustrated in (c) of FIG. 7, heat treatment (annealing/heating/cooling) is carried out with respect to the board 134 which has been tensioned and fixed to the mask frame 4. Specifically, heat baking is carried out by heat at 650° C. or higher in an inert atmosphere, and then the board 134 is cooled. From this, it is possible to enhance isotropy of crystallographic orientations of crystals constituting invar contained in the mask section 103, and to decrease the thermal expansion coefficient.

Next, as illustrated in (d) of FIG. 7, a through hole 51 is formed in the pore-formed layer 31 by laser processing (opening forming step). From this, an opening 5 is formed in the mask section 103, and thus the vapor deposition mask 102 can be manufactured which is made up of the mask section 103 and the mask frame 4. Moreover, a laser used in the laser processing is preferably an ultrashort pulse laser. In a case where an alloy such as invar having high heat conductivity is subjected to laser processing with use of the ultrashort pulse laser, it is possible to form a through hole with high accuracy of dimensions, as compared with a case where laser processing is carried out with use of a normal continuous wave laser.

The method for manufacturing the vapor deposition mask 102 in accordance with Embodiment 2 includes the heat treatment step of carrying out heat treatment with respect to the board 134 in a state in which tension is applied to the board 134 (mask section 103) made of an alloy such as invar and the end parts of the board 134 are fixed to the mask frame 4.

In a case where the heat treatment step is carried out in which the board 134 is subjected to heat treatment in a state in which tension is applied to the board 134 and the end parts of the board 134 are fixed to the mask frame 4, crystallographic orientations of crystals constituting invar contained in the mask section 103 become isotropic as shown in (b) of FIG. 5. In a case where the crystallographic orientations of crystals constituting invar become isotropic, the thermal expansion coefficient of the mask section 103 decreases.

Therefore, (i) the vapor deposition mask 102 manufactured by the method has a small thermal expansion coefficient, (ii) it is possible to inhibit thermal expansion during the vapor deposition step, and (iii) it is possible to provide a highly precise vapor deposition pattern.

<Modification Example>

In the descriptions above, the through hole 51 is formed by laser processing after the board 134 is subjected to heat baking. Note, however, that the method for manufacturing the vapor deposition mask 102 of Embodiment 2 is not limited to this, provided that at least the board 134 is subjected to heat treatment as illustrated in (c) of FIG. 7 after the board 134 is fixed to the mask frame 4 with tension as illustrated in (b) of FIG. 7.

Therefore, for example, in the processes of manufacturing the vapor deposition mask 102, it is possible to invert an order of the heat treatment step illustrated in (c) of FIG. 7 and the opening forming step illustrated in (d) of FIG. 7. That is, it is possible to carry out the heat treatment (i.e., heat baking and cooling) with respect to the board 134 as illustrated in (c) of FIG. 7 after the through hole 51 is formed by laser processing as illustrated in (d) of FIG. 7.

Even the present modification example includes the heat treatment step of carrying out heat treatment with respect to the board 134 in a state in which the end parts of the board 134 are fixed to the mask frame 4 while tension is applied to the board 134. Moreover, in the present modification example also, the through hole 51 is formed in the pore-formed layer 31 by laser processing after the end parts of the board 134 are fixed to the mask frame 4 while tension is applied to the board 134. Therefore, the present modification example can also bring about an effect similar to the above described effect.

### Embodiment 3

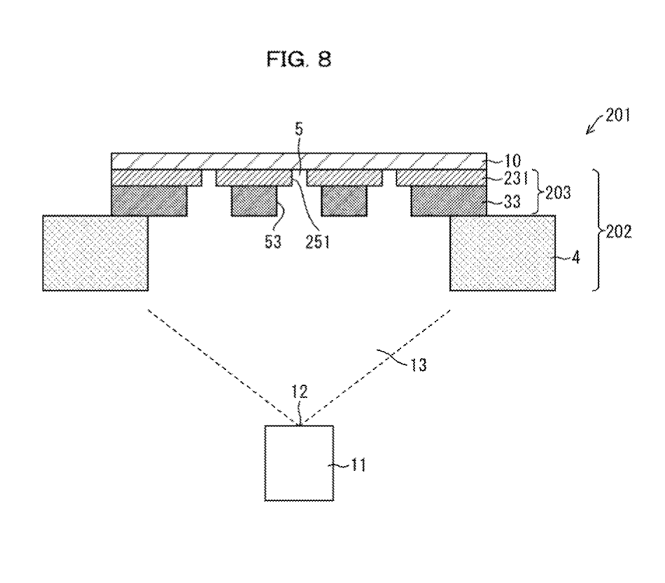

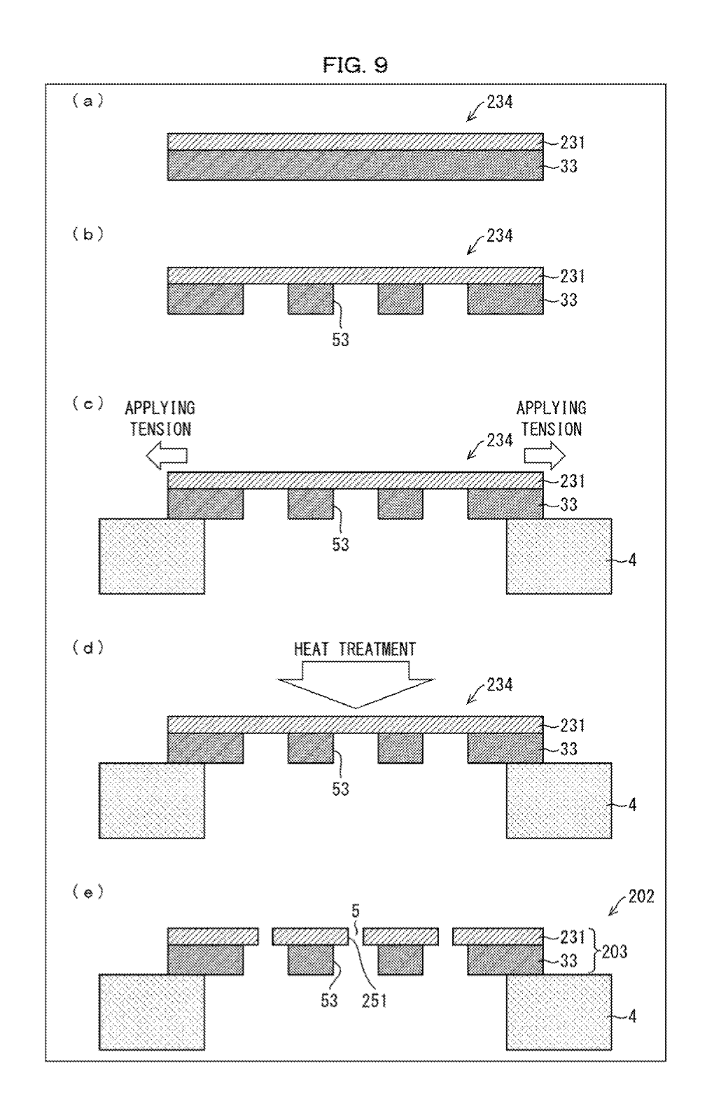

The following description will discuss another embodiment of the present invention with reference to FIG. 8 and (a) through (e) of FIG. 9. Note that, for convenience of explanation, identical reference numerals are given to constituent members having functions identical with those of the constituent members described in the above Embodiment 1, and descriptions of such constituent members are omitted here.

FIG. 8 is a cross-sectional view illustrating a configuration of main parts of a vapor deposition device 201 in accordance with Embodiment 3.

As illustrated in FIG. 8, the vapor deposition device 201 has a configuration substantially identical with that of the vapor deposition device 1 in accordance with Embodiment 1, except that a mask section 203 in a vapor deposition mask 202 is configured by a pore-formed film 231 and a supporting layer 33.

The mask section 203 in the vapor deposition mask 202 has a two-layer structure including the pore-formed film 231 (pore-formed layer) and the supporting layer 33. A through hole 251 (first through hole) is provided in the pore-formed film 231, and a through hole 53 (second through hole) is provided in the supporting layer 33. An opening 5 which is a through hole passing through from a front surface to a rear surface of the mask section 203 is constituted by the through hole 251 and the through hole 53.

The pore-formed film 231 is a thin film formed on a surface of the supporting layer 33 with use of a thin film forming technique. It is preferable that the pore-formed film 231 is a thin film made of nickel (Ni) or a thin film made of an alloy containing iron (Fe) and nickel (Ni) and has a thickness of 5 μm or less.

The thin film forming technique for forming the pore-formed film 231 can be plating, sputtering, any of various vapor depositions, or the like.

The supporting layer 33 is made of an alloy containing iron (Fe) and nickel (Ni) and is preferably made of invar, as with the supporting layer 33 in the vapor deposition mask 2 in accordance with Embodiment 1.

As with the mask section 3 of the vapor deposition mask 2 in accordance with Embodiment 1, crystals constituting an alloy contained in the mask section 203 are isotropically oriented.

In the vapor deposition mask 202, the mask section 203 includes the supporting layer 33 and the pore-formed film 231 which is a thin film coating the surface of the supporting layer 33, unlike the vapor deposition mask 2 of Embodiment 1. Therefore, it is possible to reduce a thickness of the mask section 203, as compared with the mask section 3 in the vapor deposition mask 2. With the configuration, it is possible to reduce influence of a vapor deposition shadow.

<Method for Manufacturing Vapor Deposition Mask>

The following description will discuss a method for manufacturing the vapor deposition mask 202 with reference to FIG. 9. (a) through (e) of FIG. 9 are cross-sectional views sequentially illustrating processes for manufacturing the vapor deposition mask 202 in accordance with Embodiment 3.

The followings describe a method for manufacturing the vapor deposition mask 202 in which the pore-formed film 231 is formed with use of nickel and the supporting layer 33 is formed with use of invar.

In the processes for manufacturing the vapor deposition mask 202, first, as illustrated in (a) of FIG. 9, a board 234 is prepared which is to constitute the mask section 203. The board 234 is in a cut-sheet form having a two-layer structure including the supporting layer 33 and the pore-formed film 231 that is provided on the surface of the supporting layer 33.

It is possible that a thickness of the pore-formed film 231 is 5 μm and a thickness of the supporting layer 33 is 50 μm. Moreover, it is preferable that crystals constituting the pore-formed film 231 and the supporting layer 33 are isotropically oriented.

Next, as illustrated in (b) of FIG. 9, a through hole 53 (second through hole) is formed in the supporting layer 33 by etching.

Next, as illustrated in (c) of FIG. 9, end parts of the board 234 are fixed to the mask frame 4 while the board 234 is tensioned, i.e., tension is applied to the board 234 (tensioned fixing). For example, the end parts of the board 234 can be fixed to the mask frame 4 by welding (tensioned welding).

Next, as illustrated in (d) of FIG. 9, heat treatment (annealing/heating/cooling) is carried out with respect to the board 234 which has been tensioned and fixed to the mask frame 4. Specifically, heat baking is carried out by heat at 650° C. or higher in an inert atmosphere, and then the board 234 is cooled. From this, it is possible to enhance isotropy of crystallographic orientations of crystals constituting invar contained in the mask section 203, and to decrease the thermal expansion coefficient.

Next, as illustrated in (e) of FIG. 9, a through hole 251 (first through hole) is formed in the pore-formed film 231 by laser processing (opening forming step). From this, an opening 5 is formed in the mask section 203, and thus the vapor deposition mask 202 can be manufactured which is made up of the mask section 203 and the mask frame 4.

The method for manufacturing the vapor deposition mask 202 in accordance with Embodiment 3 includes the heat treatment step of carrying out heat treatment with respect to the board 34 in a state in which tension is applied to the board 234 (mask section 203) made of an alloy such as invar and the end parts of the board 234 are fixed to the mask frame 4.

In a case where the heat treatment step is carried out in which the board 234 is subjected to heat treatment in a state in which tension is applied to the board 234 and the end parts of the board 234 are fixed to the mask frame 4, crystallographic orientations of crystals constituting invar contained in the mask section 203 become isotropic as shown in (b) of FIG. 5. In a case where the crystallographic orientations of crystals constituting invar become isotropic, the thermal expansion coefficient of the mask section 203 decreases. In a case where the pore-formed film 231 is formed from nickel by sputtering, crystals of nickel are more likely to be oriented to a (111) face and tend to be anisotropically oriented. However, in a case where the heat treatment step is carried out, crystallographic orientations of nickel contained in the pore-formed film 231 become isotropic.

Therefore, (i) the vapor deposition mask 202 manufactured by the method has a small thermal expansion coefficient, (ii) it is possible to inhibit thermal expansion during the vapor deposition step, and (iii) it is possible to provide a highly precise vapor deposition pattern.

<Modification Example>

In the descriptions above, the through hole 251 is formed by laser processing after the board 234 is subjected to heat baking. Note, however, that the method for manufacturing the vapor deposition mask 202 of Embodiment 3 is not limited to this, provided that at least the board 234 is subjected to heat treatment as illustrated in (d) of FIG. 9 after the board 234 is fixed to the mask frame 4 with tension as illustrated in (c) of FIG. 9.

Therefore, for example, in the processes of manufacturing the vapor deposition mask 202, it is possible to invert an order of the heat treatment step illustrated in (d) of FIG. 9 and the opening forming step illustrated in (e) of FIG. 9. That is, it is possible to carry out the heat treatment (i.e., heat baking and cooling) with respect to the board 234 as illustrated in (d) of FIG. 9 after the through hole 251 is formed by laser processing as illustrated in (e) of FIG. 9.

Even the present modification example includes the heat treatment step of carrying out heat treatment with respect to the board 234 in a state in which the end parts of the board 234 are fixed to the mask frame 4 while tension is applied to the board 234. Moreover, in the present modification example also, the through hole 251 is formed in the pore-formed film 231 by laser processing after the end parts of the board 234 are fixed to the mask frame 4 while tension is applied to the board 234. Therefore, the present modification example can also bring about an effect similar to the above described effect.

[Main Points]

The method in accordance with an aspect 1 of the present invention is a method for manufacturing a vapor deposition mask (2) which includes a mask section (3) and a mask frame (4), the mask section being provided with an opening (5) for forming a film of a vapor deposition material (13) on a film formation target substrate (10), and the mask section including an alloy containing iron and nickel, the method including: a heat treatment step of carrying out heat treatment with respect to the mask section in a state in which end parts of the mask section are fixed to the mask frame while tension is applied to the mask section.

According to the manufacturing method, the heat treatment is carried out in a state in which tension is applied to the mask section, and this makes it possible to enhance isotropy of orientations of crystals constituting the alloy of the mask section. From this, it is possible to (i) decrease a thermal expansion coefficient, (ii) inhibit thermal elongation of the vapor deposition mask during vapor deposition, and (iii) achieve a highly precise vapor deposition pattern.

In the method in accordance with an aspect 2 of the present invention, it is possible in the aspect 1 that the alloy has a plurality of crystal faces; and in the heat treatment step, the heat treatment is carried out such that degrees of orientation of all of the plurality of crystal faces become equal to or lower than 60%.

According to the manufacturing method, all crystallographic orientations of the alloy contained in the mask section do not exceed 60%, and isotropy of the crystallographic orientations is high. From this, directions of thermal shrinkage of the alloy become isotropic, and it is possible to further decrease a thermal expansion coefficient. As a result, it is possible to manufacture the vapor deposition mask in which thermal elongation caused due to radiation heat during vapor deposition is inhibited.

In the method in accordance with an aspect 3 of the present invention, it is possible in the aspect 1 or 2 that, in the heat treatment step, annealing is carried out at a temperature at which the alloy is recrystallized.

According to the manufacturing method, new crystal grains are generated by recrystallization of the alloy, and consequently isotropy of crystallographic orientations of the alloy is enhanced, and it is thus possible to manufacture the vapor deposition mask in which the thermal expansion coefficient is decreased.

In the method in accordance with an aspect 4 of the present invention, it is possible in the aspect 3 that, in the heat treatment step, annealing of the mask section is carried out at 650° C. or higher.

According to the manufacturing method, it is possible to further isotropically orient crystals constituting the alloy of the mask section, and it is possible to decrease the thermal expansion coefficient of the mask section.

In the method in accordance with an aspect 5 of the present invention, it is possible in any of the aspects 1 through 4 that the method further includes an opening forming step of forming an opening in the mask section, the heat treatment step being carried out after the opening forming step.

In the method in accordance with an aspect 6 of the present invention, it is possible in any of the aspects 1 through 4 that the method further includes an opening forming step of forming an opening in the mask section, the opening forming step being carried out after the heat treatment step.

In the method in accordance with an aspect 7 of the present invention, it is possible in the aspect 5 or 6 that, in the opening forming step, the opening is formed in the mask section by laser processing with use of a pulse laser.

According to the manufacturing method, it is possible to form an opening in the mask section with high accuracy of dimensions.

In the method in accordance with an aspect 8 of the present invention, it is possible in any of the aspects 1 through 7 that the alloy is invar.

In the method in accordance with an aspect 9 of the present invention, it is possible in any of the aspects 1 through 7 that the alloy is kovar.

The vapor deposition mask in accordance with an aspect 10 of the present invention includes: a mask section which is provided with an opening for forming a film of a vapor deposition material on a film formation target substrate; and a mask frame, end parts of the mask section being fixed to the mask frame in a state in which tension is applied to the mask section, the mask section including an alloy containing iron and nickel, and crystals constituting the alloy being isotropically oriented.

According to the configuration, the mask section is fixed to the mask frame in a state in which tension is applied to the mask frame, and it is therefore possible to reduce bending of the mask section during vapor deposition. From this, it is possible to inhibit floating of the mask section from the film formation target substrate, and it is possible to provide a highly precise vapor deposition pattern.

Moreover, crystals constituting the alloy contained in the mask section are isotropically oriented. From this, directions of thermal shrinkage of the alloy become isotropic, and it is possible to decrease a thermal expansion coefficient. As a result, it is possible to inhibit thermal elongation of the vapor deposition mask due to radiation heat during vapor deposition, and it is possible to provide a highly precise vapor deposition pattern.

In the vapor deposition mask in accordance with an aspect 11 of the present invention, it is possible in the aspect 10 that the alloy has a plurality of crystal faces (7); and degrees of orientation of all of the plurality of crystal faces are equal to or lower than 60%.

According to the configuration, all crystallographic orientations of the alloy contained in the mask section do not exceed 60%, and isotropy of the crystallographic orientations is high. From this, directions of thermal shrinkage of the alloy become isotropic, and it is possible to further decrease a thermal expansion coefficient. As a result, it is possible to inhibit thermal elongation of the vapor deposition mask due to radiation heat during vapor deposition, and it is possible to provide a highly precise vapor deposition pattern.

In the vapor deposition mask in accordance with an aspect 12 of the present invention, it is possible in the aspect 10 or 11 that the mask section includes a pore-formed layer (31, pore-formed film 231) and a supporting layer (33) which is thicker than the pore-formed layer; the pore-formed layer is provided with a first through hole (through hole 51, 251) which corresponds to the opening; the supporting layer is provided with a second through hole (through hole 53) which corresponds to the opening; and an opening width of the opening is defined by an opening width of the first through hole.

According to the configuration, the supporting layer, which is thicker than the pore-formed layer, is provided separately from the pore-formed layer that defines the opening in the mask section, and this makes it possible to improve strength of the vapor deposition mask and to inhibit bending.

Further, the opening in the vapor deposition mask is defined by the first through hole that is provided in the pore-formed layer which is thinner than the supporting layer, and this makes it possible to reduce influence of a vapor deposition shadow.

In the vapor deposition mask in accordance with an aspect 13 of the present invention, it is possible in any of the aspects 10 through 12 that the alloy is invar.

In the vapor deposition mask in accordance with an aspect 14 of the present invention, it is possible in any of the aspects 10 through 12 that the alloy is kovar.

The vapor deposition device in accordance with an aspect 15 of the present invention includes: the vapor deposition mask described in any one of the aspects 10 through 14; and a vapor deposition source (11) for depositing the vapor deposition material onto the film formation target substrate via the opening provided in the vapor deposition mask.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### INDUSTRIAL APPLICABILITY

The present invention is suitably applicable to manufacturing of an organic EL element, an inorganic EL element, an organic EL display device including the organic EL element, an inorganic EL display device including the inorganic EL element, and the like.

### REFERENCE SIGNS LIST

1, 101, 201: Vapor deposition device
2, 102, 202: Vapor deposition mask
3, 103, 203: Mask section
4: Mask frame
5: Opening
6: Crystal grain
7: Crystal face
10: Film formation target substrate
11: Vapor deposition source
31: Pore-formed layer
231: Pore-formed film
33: Supporting layer
51, 251: Through hole (first through hole)
53: Through hole (second through hole)

1. A method for manufacturing a vapor deposition mask which includes a mask section and a mask frame, the mask section being provided with an opening for forming a film of a vapor deposition material on a film formation target substrate, and the mask section including an alloy containing iron and nickel,
said method comprising:
a heat treatment step of carrying out heat treatment with respect to the mask section in a state in which end parts of the mask section are fixed to the mask frame while tension is applied to the mask section.

2. The method as set forth in claim 1, wherein:
the alloy has a plurality of crystal faces; and
in the heat treatment step, the heat treatment is carried out such that degrees of orientation of
all of the plurality of crystal faces become equal to or lower than 60%.

3. The method as set forth in claim 1, wherein:
in the heat treatment step, annealing is carried out at a temperature at which the alloy is recrystallized.

4. The method as set forth in claim 3, wherein:
in the heat treatment step, annealing of the mask section is carried out at 650° C. or higher.

5. The method as set forth in claim 1, further comprising:
an opening forming step of forming an opening in the mask section,
the heat treatment step being carried out after the opening forming step.

6. The method as set forth in claim 1, further comprising:
an opening forming step of forming an opening in the mask section,
the opening forming step being carried out after the heat treatment step.

7. The method as set forth in claim 5, wherein:
in the opening forming step, the opening is formed in the mask section by laser processing with use of a pulse laser.

8. The method as set forth in claim 1, wherein the alloy is invar.

9. The method as set forth in claim 1, wherein the alloy is kovar.

10. A vapor deposition mask comprising:
a mask section which is provided with an opening for forming a film of a vapor deposition material on a film formation target substrate; and
a mask frame,
end parts of the mask section being fixed to the mask frame ill a state in which tension is applied to the mask section,
the mask section including an alloy containing iron and nickel, and
crystals constituting the alloy being isotropically oriented.

11. The vapor deposition mask as set forth in claim 10, wherein:
the alloy has a plurality of crystal faces; and
degrees of orientation of all of the plurality of crystal faces are equal to or lower than 60%.

12. The vapor deposition mask as set forth in claim 10, wherein:
the mask section includes a pore-formed layer and a supporting layer which is thicker than the pore-formed layer;
the pore-formed layer is provided with a first through hole which corresponds to the opening;
the supporting layer is provided with a second through hole which corresponds to the opening; and
an opening width of the opening is defined by an opening width of the first through hole.

13. The vapor deposition mask as set forth in claim 10, wherein the alloy is invar.

14. The vapor deposition mask as set forth in claim 10, wherein the alloy is kovar.

15. A vapor deposition device comprising:
a vapor deposition mask recited in claim 10; and
a vapor deposition source for depositing the vapor deposition material onto the film formation target substrate via the opening provided in the vapor deposition mask.

16. A method for manufacturing an EL display device wherein:
a luminescent layer of the EL display device is formed as a vapor-deposited film by depositing a vapor deposition material, which has been emitted from a vapor deposition source via an opening of a vapor deposition mask, onto a film formation target substrate,
the vapor deposition mask including a mask section and a mask frame, the mask section being provided with the opening for forming a film of the vapor deposition material on the film formation target substrate, end parts of the mask section being fixed to the mask frame in a state in which tension is applied to the mask section, the mask section including an alloy containing iron and nickel, crystals constituting the alloy being isotropically oriented, and the vapor deposition source being arranged across the vapor deposition mask from the film formation target substrate.
